(19) United States
(12) Patent Application Publication
(10) Pub. No.: US 2006/0060941 A1
(43) Pub. Date: Mar. 23, 2006

(54) Polysilicon sidewall spacer lateral bipolar transistor on SOI

(76) Inventors: I-Shan Michael Sun, Toronto (CA); Wai Tung Ng, Thornhill (CA); Koji Kanekiyo, Moriyama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/210,881

(22) Filed: Aug. 25, 2005

Related U.S. Application Data
(60) Provisional application No. 60/604,714, filed on Aug. 27, 2004.

(51) Int. Cl. H01L 29/00

(52) U.S. Cl. 257/557

(57) ABSTRACT

Consistent with an aspect of the present invention, a lateral bipolar transistor is provided that exhibits similar performance as that of high speed vertical bipolar junction transistors. The lateral bipolar transistor includes a polysilicon side-wall-spacer (PSWS) that forms a contact with the base of the transistor, and thus avoids the process step of aligning a contact mask to a relatively thin base region. The side wall spacer allows self-alignment of the base/emitter region, and has reduced base resistance and junction capacitance. Accordingly, improved cutoff frequency (fτ) and maximum oscillation frequency (fmax) can be achieved. Moreover, this novel topology enables the realization of Bipolar CMOS (BiCMOS) technology on insulating substrates, such as SOI.

THIS APPLICATION CLAIMS THE BENEFIT OF PROVISIONAL APPLICATION No. 60/604,714 FILED ON Aug. 27, 2004, THE CONTENTS OF WHICH ARE INCORPORATED BY REFERENCE HEREIN.

### FIELD OF THE INVENTION

The present invention is generally related to semiconductor devices, and bipolar transistors in particular.

### DESCRIPTION OF THE RELATED ART

Significant growth in wireless communications has prompted the need for smaller and faster transistors. As a result, substantial efforts have been made to improve radio frequency (RF) integrated circuit (IC) technologies by integrating as many sub-systems as possible onto a silicon chip. Further device miniaturization, however, are required in order to integrate entire RF systems onto a single chip (System-on-Chip, SoC), and improved manufacturing efficiencies are necessary for such RF SoCs to become commercially viable.

For silicon-based technology, advances in both complementary metal oxide semiconductor (CMOS) and bipolar devices, have yielded improved high frequency performance for these types of devices and thus both continue to be used in high-speed and RF applications. For example, n-channel metal-oxide-semiconductor field effect transistors (n-MOSFETs) and silicon-germanium heterojunction bipolar transistors (SiGe-HBTs) can achieve a cut-off frequency (f_{τ}) above 100 and 200 GHz, respectively. To effectively utilize both types of devices, one conventional approach involves bipolar CMOS (BiCMOS) processes that permit integration of more complex circuits on the same chip. However, as BiCMOS devices are scaled downward to improve speed, such processes are becoming increasingly more expensive because of increased costs of developing lithographic technologies with greater resolution. In addition, with the advent of silicon germanium (SiGe) heterojunction bipolar transistors (HBT), the number of mask steps required to make BiCMOS devices has increased. Moreover, due to the incorporation of passive RF components, such as inductors and capacitors, additional mask steps are required. As a result, wafer costs increase by approximately 1.3 times for each generation of lithography advancement. Therefore, the cost for implementing a 0.13 μm SiGe BiCMOS is more than five times that of the 0.35 μm process, and may even be prohibitive for implementing 90 nm or 70 nm lithography processes. Such high processing costs are a significant obstacle in achieving an economical RF SoC.

For SoC applications, silicon-on-insulator (SOI) is a desirable substrate since it offers electrical isolation, reduced crosstalk and less substrate noise. Also, the use of SOI substrate will improve the performance of passive components such as inductors and capacitors. CMOS transistors on SOI also have improved speed due to reduced parasitic capacitances. However, the vertical bipolar structure associated with the SiGe HBT and SOI-CMOS devices requires that the SOI layer be at least a few microns thick, thereby rendering integration of these devices difficult. Although SiGe-HBTs have been fabricated on thin-film SOI, their performance is not nearly as good as those provided on a silicon substrate. Moreover, the additional cost of the SOI wafers makes such BiCMOS processes even less attractive.

Another alternative involves a lateral bipolar structure, in which current flows in the same horizontal plane, and if integrated with CMOS transistors, in the same plane as the CMOS transistors. This configuration permits adjustment of the thickness and/or doping of the SOI layer to optimize the CMOS transistors, without degrading bipolar device performance. In addition, SOI lateral bipolar transistors have been shown, through simulation, to effectively reduce parasitics and improve both cutoff frequency (f_{τ}) and maximum oscillation frequency (fₘₐₓ). In particular, lateral SOI SiGe HBTs can theoretically achieve fₘₐₓ of over 500 GHz, exceeding some of the fastest vertical HBTs. Moreover, lateral bipolar junction transistors (LBJTs) can be fabricated with a minimal number of additional masks, and are thus cost effective.

However, there have been only a few successful demonstrations of lateral bipolar transistors that are fast enough for most RF applications. In particular, a device with a cobalt silicide base contact has been fabricated having an f_{τ} in the range of 4-15 GHz a maximum fₘₐₓ of 67 GHz. By way of comparison, commercially available vertical BJTs operate with f_{τ}/fₘₐₓ at around 20/30 GHz.

Accordingly, there is a need for a lateral BJT having performance characteristics suitable for RF applications.

### SUMMARY OF THE INVENTION

Consistent with an aspect of the present invention, a semiconductor device is provided, which comprises a substrate and a semiconductor layer provided on the substrate. A collector region having a first conductivity type is provided in the semiconductor layer, and an emitter region having the first conductivity type is provided in the semiconductor layer laterally spaced from the collector region. A base region having a second conductivity type is provided between the emitter and collector regions. The base region has a first concentration of impurities of the second conductivity type. The semiconductor device also includes a contact region provided in the base region. The contact region has a second concentration of the impurities of the second conductivity type greater than the first concentration. Additionally, a first conductive layer having a sidewall is provided on a surface of the substrate. Further, a second conductive layer is provided having a first portion contacting the sidewall and a second portion contacting the contact region.

Consistent with an additional aspect of the present invention, a semiconductor device is provided which comprises a substrate, a semiconductor layer provided on the substrate, and a collector region provided in the semiconductor layer, the collector region having a first conductivity type. A base region is also provided in the semiconductor layer having a second conductivity type, and the collector region surrounds the base region. An emitter region is further provided in the semiconductor layer such that the base region surrounds the emitter region.

In accordance with an additional aspect of the present invention, a semiconductor device is provided which comprises a substrate, a semiconductor layer provided on the substrate, and an emitter region provided in the semiconductor layer. The emitter region has a first conductivity type and surrounds a base region provided in the semiconductor layer. A collector region is also provided in the semiconductor layer such that the base region surrounds the collector region.

Consistent with another aspect of the present invention, a method of manufacturing a semiconductor device is provided which comprises forming a semiconductor layer having a first conductivity type and a first concentration of impurities of the first conductivity type on a substrate. The method also includes forming an insulating layer on the surface of the substrate, and forming a first conductive layer on the insulating layer. The method further includes patterning the insulating and first conductive layers such that a sidewall of the first conductive layer is aligned with a sidewall of the insulating layer, and forming a second conductive layer on the sidewalls of the insulating and first conductive layers. Moreover, the method includes forming, in the semiconductor layer, a first doped region having the second conductivity type in contact with the second conductive layer, forming a second doped region having the first conductivity type in the semiconductor layer. The second doped region has a second concentration of impurities of the first conductivity type and is spaced from a portion of the semiconductor layer having the first concentration of the impurities of the first conductivity type. The first doped region is provided between the second doped region and the portion of the semiconductor layer.

Additional aspects and advantages of the invention will be set forth in part in the description which follows, and in part will be obvious from the description, or may be learned by practice of the invention. The aspects and advantages of the invention will be realized and attained by elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate several embodiments of the invention and together with the description, serve to explain the principles of the invention.

### BRIEF DESCRIPTION OF THE DRAWINGS

FIG. 1 is a perspective view of a transistor consistent with an aspect of the present invention;

FIGS. 2(a)-2(j) illustrate process steps in forming a transistor consistent with a further aspect of the present invention;

FIGS. 3(a) and 3(b) illustrate process steps in forming a transistor consistent with an additional aspect of the present invention;

FIG. 4 illustrates plots of doping concentrations consistent with an aspect of the present invention;

FIGS. 5(a) and 5(b) illustrate perspective and plan views of a transistor consistent with an additional aspect of the present invention;

FIGS. 6(a) and 6(b) illustrate perspective and plan views of a transistor consistent with a further aspect of the present disclosure;

FIG. 7 illustrate a scanning electron micrograph (SEM) of a cross-section of a transistor consistent with an aspect of the present invention;

FIG. 8 illustrates plots of collector and base current vs. base voltage of devices consistent with aspects of the present invention;

FIGS. 9(a) and 9(b) illustrate plots of collector current vs. base voltage of devices consistent with aspects of the present invention;

FIG. 10 illustrates plots of collector current vs. collective voltage of devices consistent with aspects of the present invention;

FIG. 11 illustrates plots of current vs. breakdown voltage of devices consistent with aspects of the present invention;

FIG. 12 illustrates plots of F_{T} and Fₘₐₓ of devices consistent with aspects of the present invention; and

FIG. 13 illustrates plots of breakdown voltage values vs. peak f_{T} of devices consistent with aspects of the present invention and known bipolar junction transistors.

### DESCRIPTION OF THE PREFERRED EMBODIMENTS

Consistent with an aspect of the present invention, a lateral bipolar transistor is provided that exhibits similar performance as that of high speed vertical bipolar junction transistors. The lateral bipolar transistor includes a polysilicon side-wall-spacer (PSWS) that forms a contact with the base of the transistor, and thus avoids the process step of aligning the contact mask to a relatively thin base region. The side wall spacer allows self-alignment of the base/emitter region, and has reduced base resistance and junction capacitance. Accordingly, improved f_{τ} and fₘₐₓ. can be achieved. The lateral bipolar transistor consistent with the present invention can be fabricated on the same substrate as SOI-CMOS devices and other CMOS devices such as FinFETs.

Reference will now be made in detail to the present preferred embodiments of the invention, examples of which are illustrated in the accompanying drawings. Wherever possible, the same reference numbers will be used throughout the drawings to refer to the same or like parts.

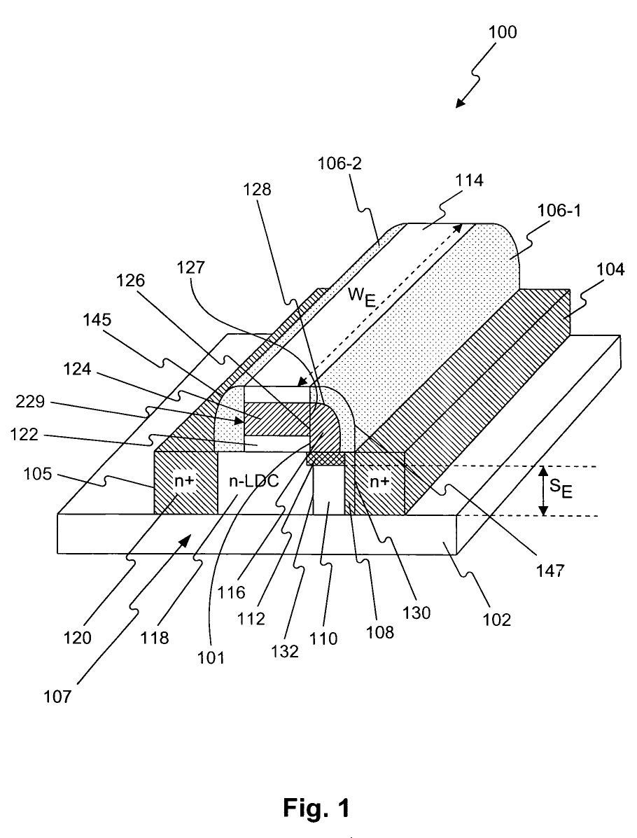

FIG. 1 illustrates a perspective view of a semiconductor device including lateral bipolar junction transistor 100 consistent with an aspect of the present invention. Transistor 100 is typically provided on substrate 102, which is typically an insulating substrate such as a buried or so-called Box oxide substrate, although other substrates, such as semiconductor substrates may also be used. A semiconductor layer 105, typically made of single crystal silicon, is provided on substrate 102. N+ emitter region 104 is formed in semiconductor layer 105, as well as collector region 107 including a heavily doped n+ collector portion 120 and lightly doped n collector (n-LDC) portion 118. A p-type, relatively lightly doped or intrinsic, base region 110 is provided between emitter 104 and collector 107. A p+contact region or doped region 112 having a higher p-type impurity concentration than p-type base 110 is provided in the p-type base in order to facilitate an electrical connection to base 110. Base 110, collector 107 and emitter 104 are doped regions and are laterally formed in semiconductor layer 105.

A three layer stack 229 including insulating layer 122 (typically silicon dioxide), a conductive layer 124 (typically p+ polysilicon), and insulating layer 114 (typically silicon dioxide) is provided on the surface of semiconductor layer 105. Insulating layer 114, however, may be removed in order to facilitate formation of a silicide contact, to be discussed in greater detail below. Conductive layer 124 is electrically coupled to contact region 112 through conductive layer 116, which is typically a p+ polysilicon sidewall spacer (PSWS). A surface 127 of conductive layer 116 is provided on sidewall 126 of conductive layer 124, as well as sidewall 101 of insulating layer 122.

Insulating layer 106-1, typically silicon nitride, is provided on a second surface 128 of conductive layer 116, and an additional insulating layer 106-2, also typically a nitride, is provided on an opposite side of three layer stack 229 including layers 122, 124 and 114. N+ collector portion 120 is self-aligned with surface 145 of insulating layer 106-2, and edge 130 of n+ emitter region 104 may be self-aligned with surface 147 of insulating layer 106-1. For high voltage (“HV”) devices consistent with the present invention, edge 132 of base 110 may be aligned with sidewall 126 of conductive layer 124, and for high speed applications (“HS”) edge 132 may be self-aligned with surface 128 of conductive layer 116. It is noted, however, that even though such self-alignment can be achieved, lateral diffusion of impurities can occur such that n-type dopants can diffuse from self-aligned collector portion 120 into n-LDC portion 118, as well as from emitter 104 into base 110. For example, n-type lateral diffusion region 108 can form between base 110 and emitter 104, for example. Nevertheless, the above-noted regions are considered self-aligned because the implants used to form these regions are carried out in a self-aligned manner, as discussed in greater detail below.

The emitter area of transistor 100 is defined by the width of emitter (W_{E}) and silicon layer 100 that is equivalent to the emitter size (S_{E}).

As noted above, conductive layer 116 facilitates connection between extrinsic base conductive layer 124 and base 110 or intrinsic base of transistor 100. Moreover, emitter 104 and base 110 can be laterally self-aligned to dimensions less than the resolution achievable with most conventional lithographic techniques.

In conventional bipolar junction transistor designs, the extrinsic base (including a heavily doped p-type polysilicon or diffused region) comes into contact with the intrinsic base, but can also contact the collector region due to mask alignment limitations and related errors. Such base-collector contact can greatly increase the capacitance between these two regions. In accordance with an aspect of the present invention, however, the base-collector capacitance is substantially reduced by forming the base oxide insulating layer 122 relatively thick. Moreover, this prevents dopant contamination out-diffused from layer 124 into n-LDC region of 118, or intrinsic collector of transistor 100.

In addition, base parasitic capacitance is reduced because the thickness of conductive layer 116 as well as underlying contact region 112 can be made relatively thin and controlled to be within 100 nm. Moreover, conductive layer 116 is self-aligned to base 110 to further reduce base parasitic capacitance. It is noted that in conventional lateral bipolar transistors, the base width is defined by the lateral width of the p-base region, but made smaller by controlling, albeit somewhat imprecisely, the lateral straggle of the emitter ion-implant and subsequent thermal annealing. Consistent with a further aspect of the present invention, the base and emitter implants are self-aligned with the formation of conductive layer 116 and insulating layer 106-1, as discussed in greater detail below. With this technique, base 110 and emitter 104 can be self-aligned to less than 0.15 μm, and even though the base width can be made relatively narrow, it is nonetheless accurately controlled.

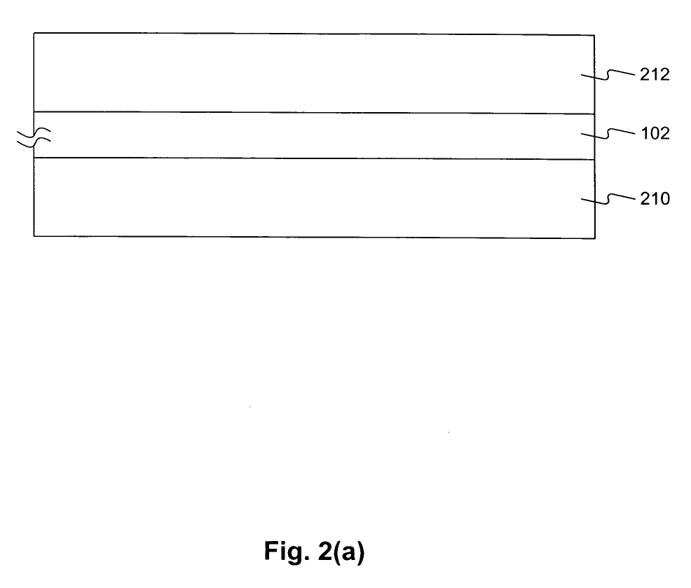

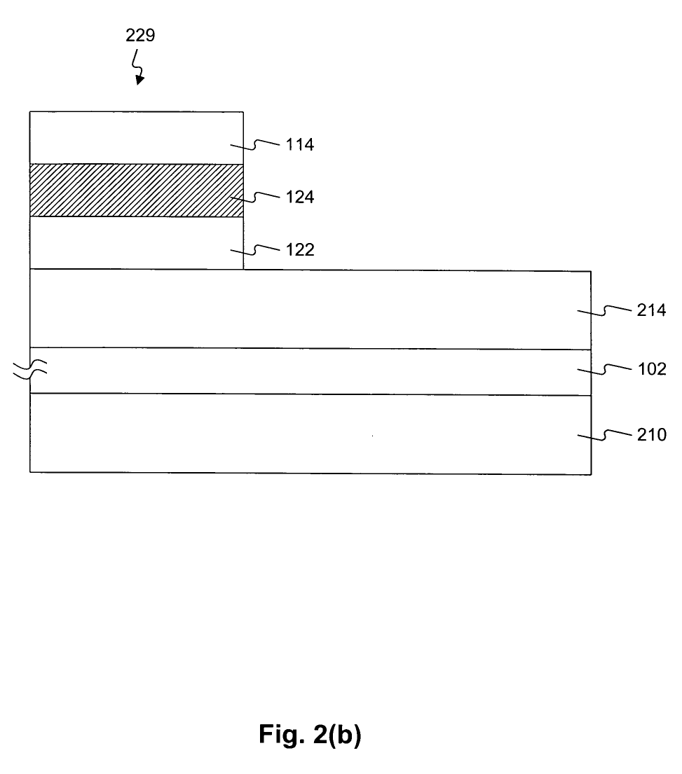

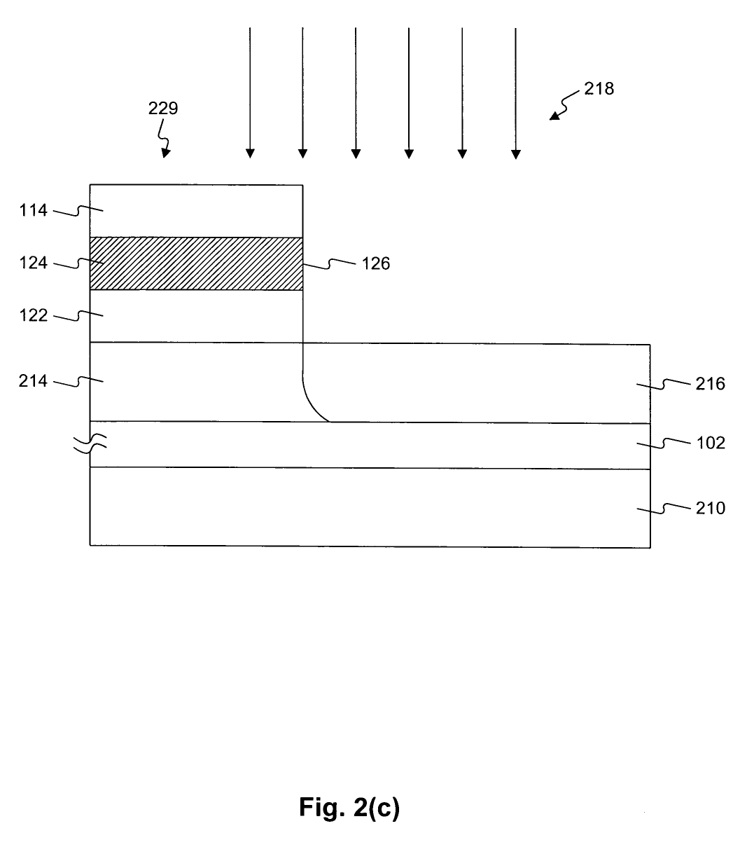

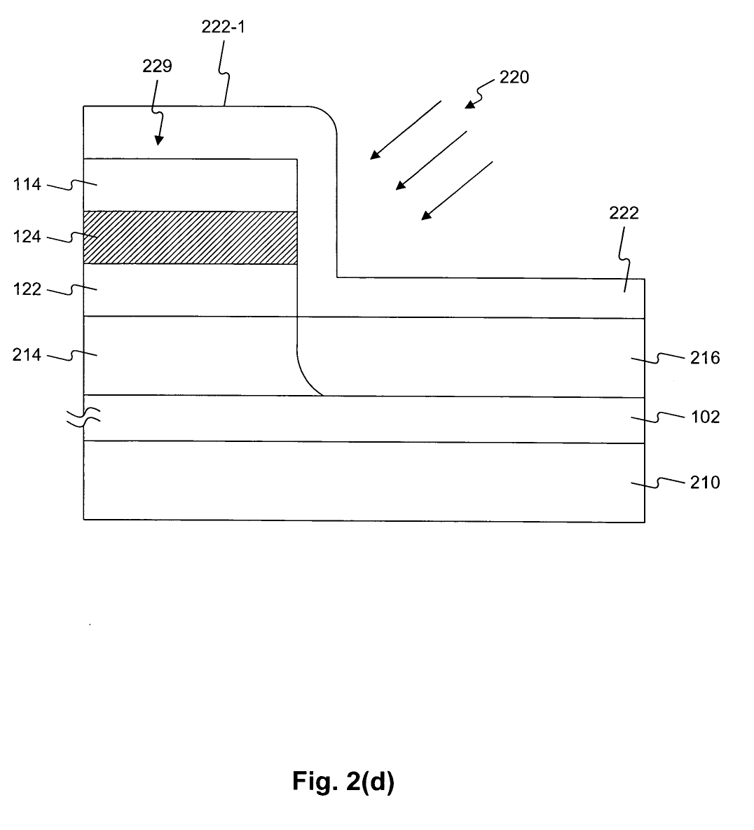

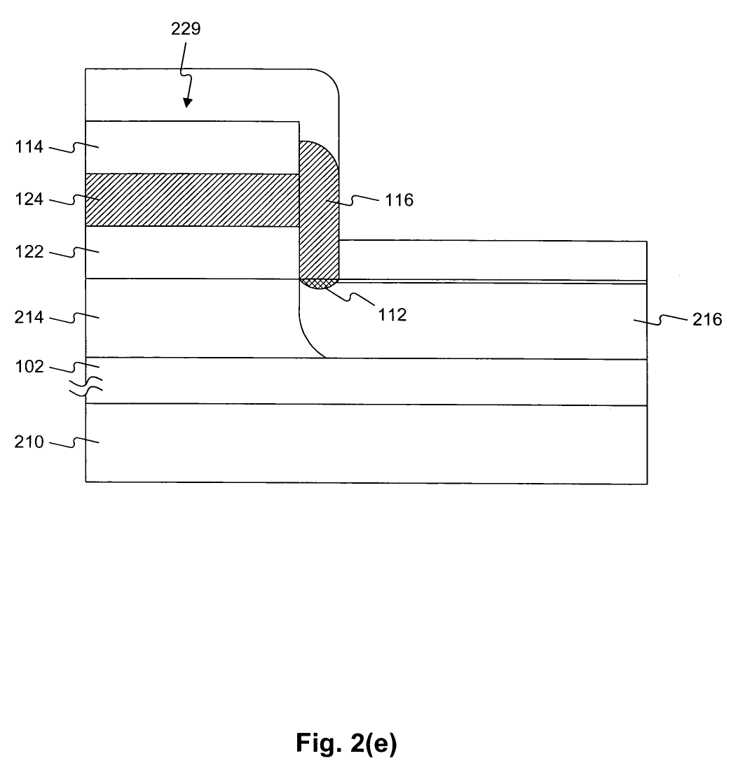

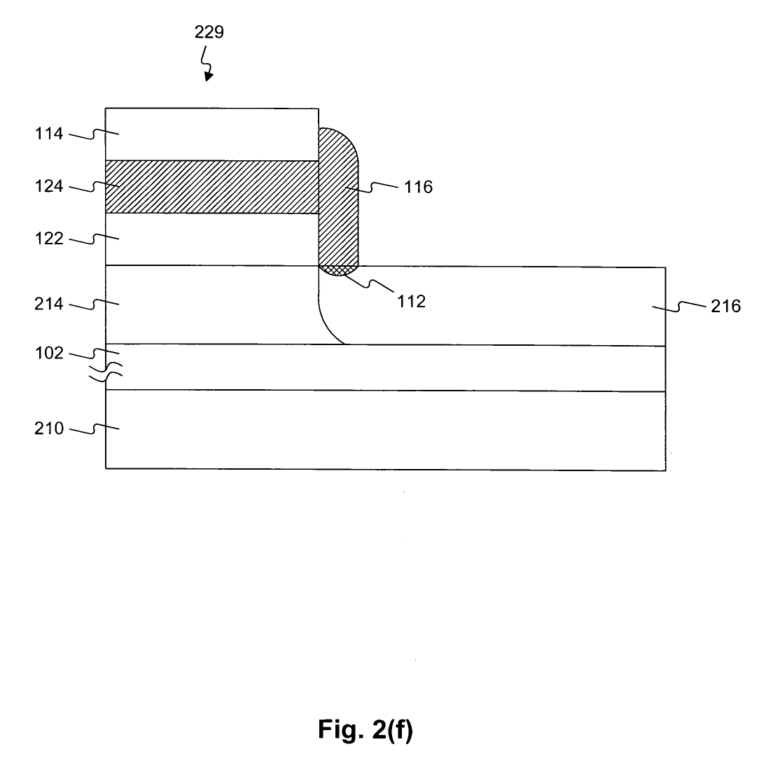

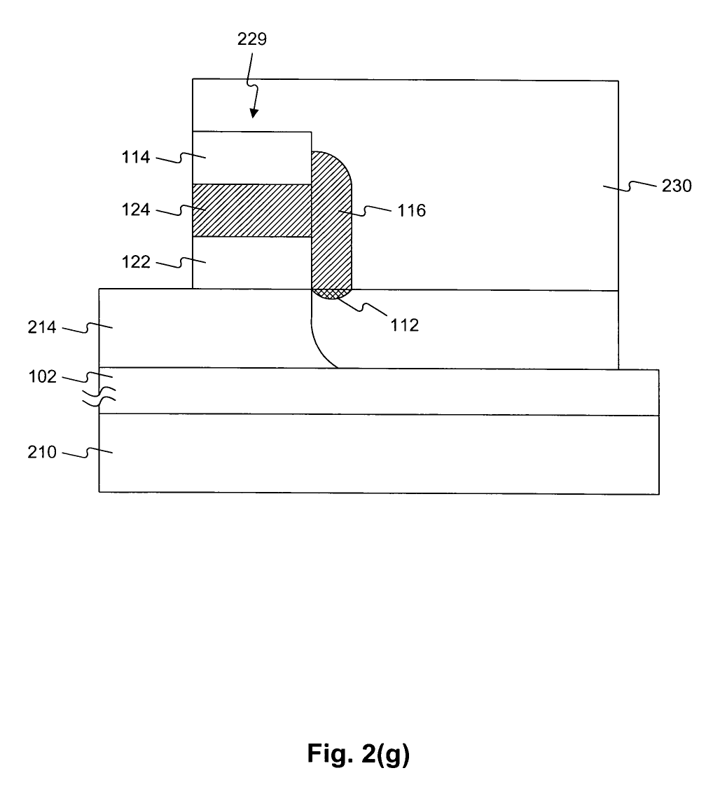

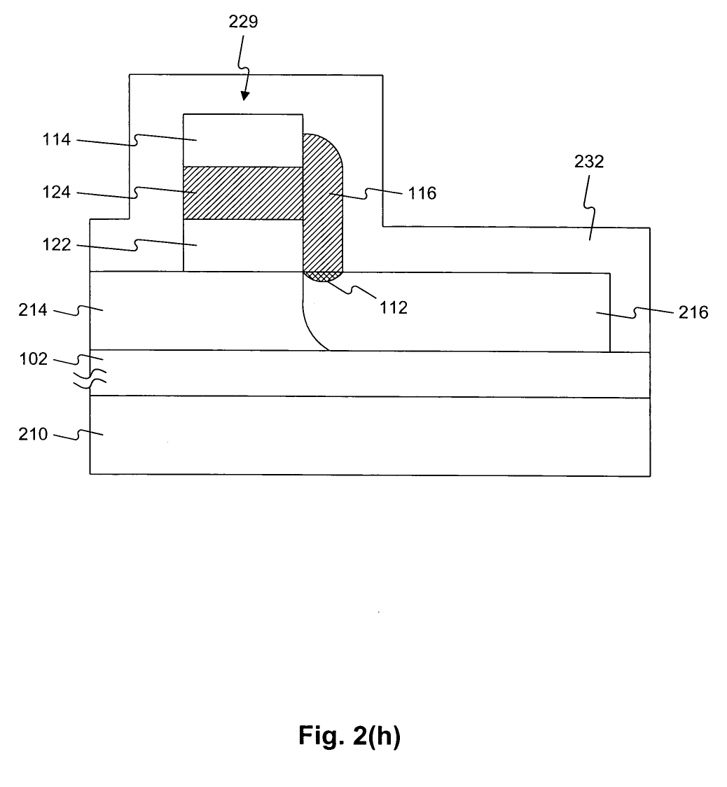

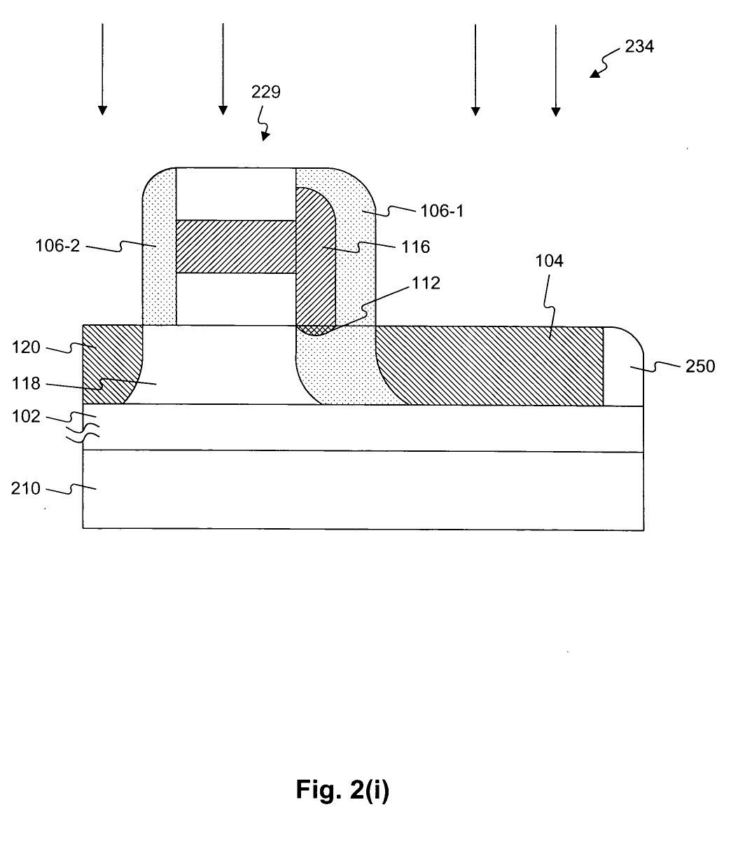

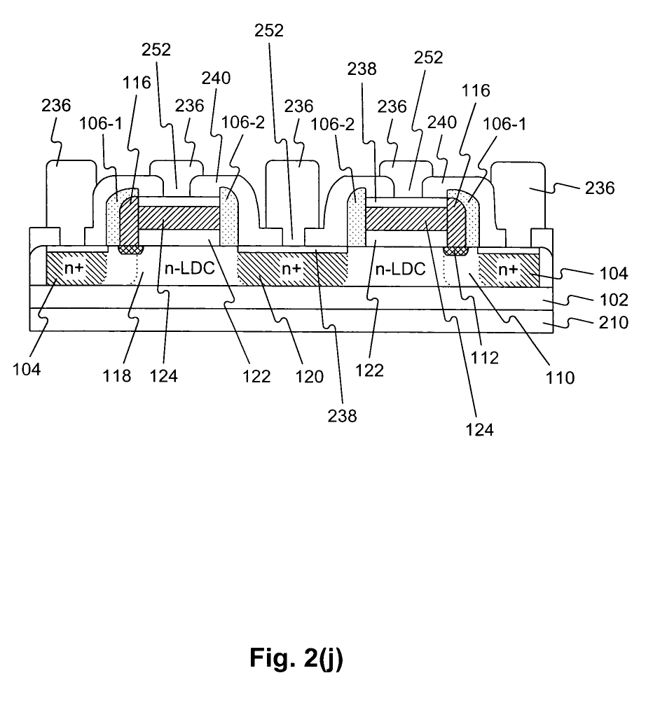

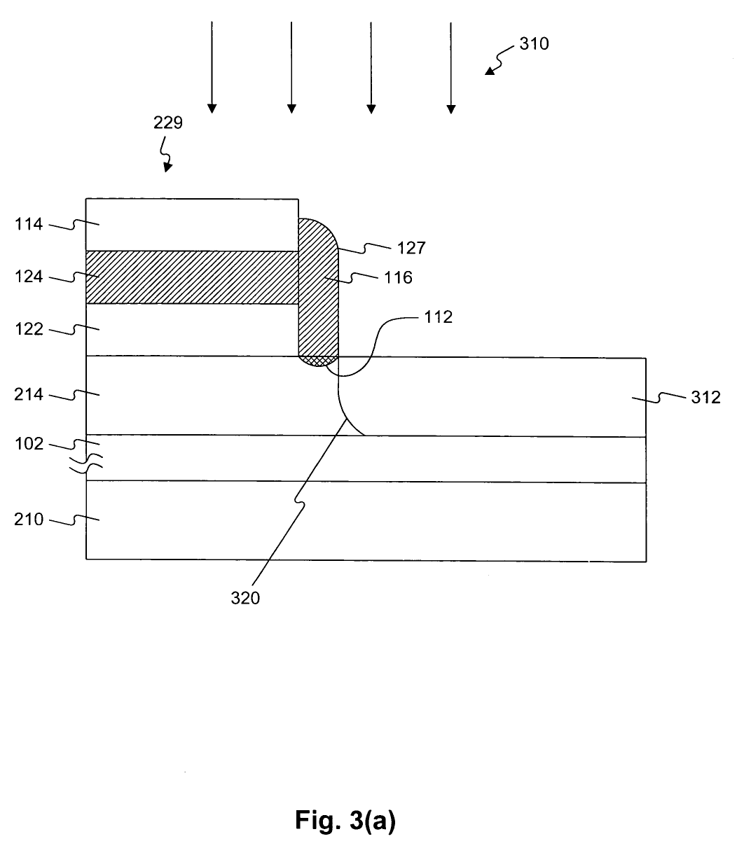

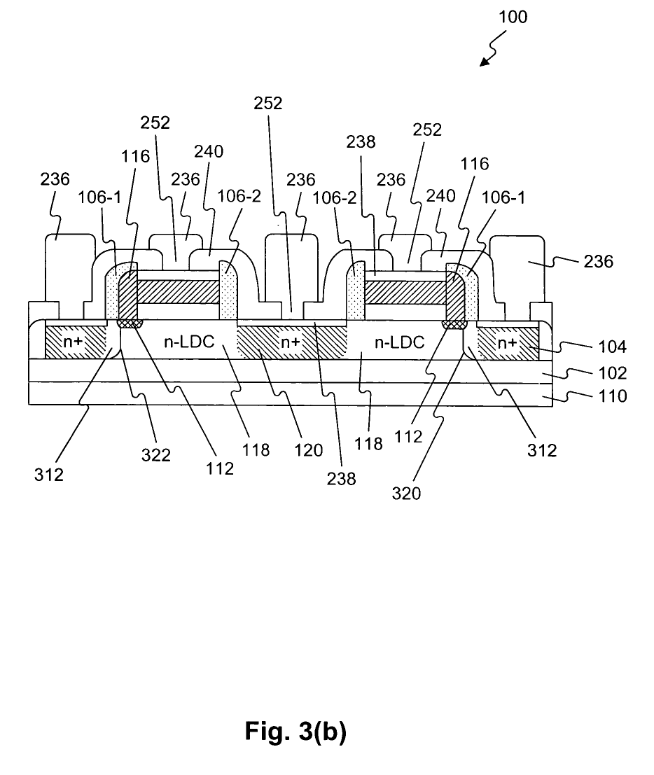

As noted above, in one embodiment of the present invention, the base width can be made larger for high voltage (HV) applications, and narrower for high speed (HS) applications. Both types of devices, however, can be integrated on the same semiconductor wafer, and both can be made with conventional 0.35 micron processes, such as that used by AKM Semiconductor, Inc. Fabrication of transistor 100 suitable for HV applications will first be described with reference to FIGS. 2(a) to 2(j), followed by a description of a process for making transistor 100 for HS applications with reference to FIGS. 3(a) and 3(b).

As shown in FIG. 2(a), a process for fabricating transistor 100 for HV applications begins by providing a uni-bond SOI substrate including a p-type substrate 210, insulating or Box oxide layer 102 having a thickness of 400 nm, for example, and a p-type semiconductor layer 212 having a thickness of 190 nm, for example, and a typical doping concentration of about 10¹⁵ cm⁻³.

After depositing the Initial Field Oxide (IFO, not shown), the entire surface of semiconductor layer 212 is implanted with an n-type dopant, such as phosphorus at an energy of 120 keV. The energy is selected such that phosphorus can fully penetrate semiconductor layer 212, to thereby form n-type semiconductor layer 214 (FIG. 2(b)). Preferably, layer 214 is n-type throughout, without any p-type region remaining at the semiconductor layer 214/insulating layer 102 interface. A portion of semiconductor layer 214 forms the Lightly-Doped Collector (LDC) portion 118 in the completed device. A dose level of 2×10¹² cm⁻² may be used to produce a concentration of roughly 10¹⁷ cm⁻³. Following the removal of the IFO, base oxide or insulating layer 122 is deposited to a thickness of 200 nm. Thereafter, an un-doped polysilicon layer is deposited having a thickness of 350 nm, followed by a boron implant (dose of 5×10¹⁵ cm⁻²) to form a highly doped base-polysilicon layer or conductive layer 124, which minimizes the extrinsic base resistance. Thermal annealing at 950° C. is next applied for 30 sec to drive-in dopant in both layer 214 and conductive layer 124.

An additional 200 nm of oxide (a top-oxide or insulating layer 114) is then deposited on top of conductive layer 124. In a first photolithography step, a Poly-Base mask (PBS) defines the lateral base-emitter region by exposing a portion of semiconductor layer 214. Then, preferably in a single etching step, corresponding portions of layers 122, 124 and 114 are removed to form stack 229. In addition, the sidewalls of each of layers 122, 124 and 114 are self-aligned. The resulting structure is shown in FIG. 2(b). Note that the left side of structure is shown truncated for simplicity, but would otherwise extend to the left where similar etching would take place.

In FIG. 2(c), a second mask is applied to expose the active regions for transistor 100 suitable for HV applications. In particular, a layer of photoresist (not shown) is selectively patterned to expose portions of semiconductor layer 214. Next, p-type region 216 is then formed preferably through a double ion implant 218 of BF₂ (120 keV, 7×10¹² cm⁻²) and boron (50 keV, 5×10¹² cm⁻²) to yield a uniform doping profile throughout p-type region 216. Unlike conventional implants, in which the substrate is oriented at an angle of 7°, substrate 210 is typically not tilted (i.e. it has 0° tilt) during implant 218 in order to minimize shadowing effect. As a result, each vertical base region receives the same dose. With an angle of 7°, however, the implant doses are offset and yield inconsistent base widths. Nevertheless, since 0° tilt may be difficult to achieve, alternative small non-zero angle implantations can be used with the precise angle optimized to obtain the best yield.

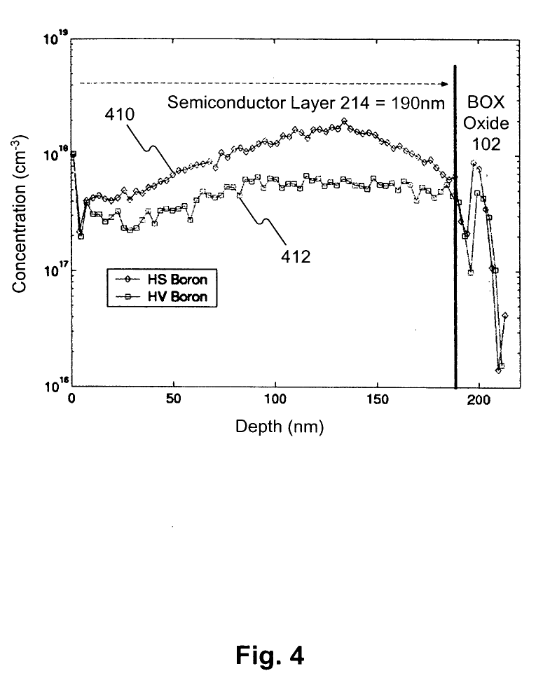

FIG. 4 shows a secondary ion mass spectrometry data (SIMS) associated with implant 218 (curve 412). Note that the p-type dopant concentration remains substantially constant over the entire width of region 216, i.e., the thickness of semiconductor layer 214.

P-type region 216, part of which will form base 110 in the completed device, is aligned sidewall 126 of conductive layer 124. After removing the photoresist, 100 nm of un-doped polysilicon are deposited across the entire wafer (FIG. 2(d)). The polysilicon is doped with a 45° tilted shallow implant 220 of boron (10¹⁴ cm⁻², 20 keV) and BF₂ (10¹⁴ cm⁻², 80 keV), in order for sufficient dopant to penetrate through the polysilicon layer. Since all four side-planes of stack 229 are encircled with polysilicon sidewalls, implantation 220 is performed at four incident angels (0°, 90°, 180°, 270°), each angle implanting p-type impurities into a different face of stack 229. As a result, the polysilicon deposited on each side of stack 229 receives a thorough dose, and p-type poly-silicon layer 222 is thus formed. At this stage, polysilicon layer 222 remains intact, as shown in FIG. 2(d).

Next, substrate 210 is subjected to a rapid thermal anneal (RTA) step to activate the implanted p-type dopant in poly-silicon layer 222. In addition, p+ out-diffusion into region 216 takes place, thereby forming contact region 112, which reduces the contact resistance between conductive region 115 and base 110 (FIG. 2(e)). After such annealing, an anisotropic etch-back step is carried out to remove 100 nm (with 10% over-etching) of poly-silicon layer 222 over insulating layer 114 and over most of region 216, leaving only the vertical part of layer 222, i.e. conductive layer 116, adjacent layers 122, 124 and 114 (FIG. 2(f)).

In a third photolithography step, a collector open (COP) mask defines the n+collector portion 120. In particular, photoresist 230 is deposited and pattern as shown in FIG. 2(g), followed by etching through layers 114, 124 and 122 to expose the designated collector region in layer 214. This photolithography step defines the final width of the conductive layer 124 as well as the width of LDC portion 118. This width may be chosen to balance the speed with breakdown voltage of the transistor.

During etching of the conductive layer 124, portions of semiconductor layer not covered by either photoresist 230 or layer 124 will also be removed in order to improve device isolation without additional masking or processing steps. As a result, additional trench isolation forming steps are unnecessary in accordance with an aspect of the present invention.

Preferably, PBS and COP masks are designed so that the collector portion 120 and emitter 104 have a sufficiently large area to accommodate at least one contact hole, but small enough to reduce parasitic capacitance and the overall device area.

Next, in FIG. 2(h), photoresist 230 is removed and insulating layer 232 is deposited. Insulating layer 232 may be silicon nitride having a thickness of 150 nm. In FIG. 2(i), insulating layer 232 is etched back with 10% over-etching to form 30 nm wide insulating layers 106-1 and 106-2 (FIG. 2(i)). As noted above, and further shown in FIG. 2(i), insulating layers 106-1 and 106-2 are provided on opposite sides of etched stack 229.

In FIG. 2(i), n+ collector portion 120 and emitter 104 are formed simultaneously by double implantations 234 of arsenic (40 keV, 10¹⁵ cm⁻²) and phosphorus (90 keV, 5×10¹⁵ cm⁻²). Silicon nitride insulating layer 250 remains adjacent to emitter 104, thereby providing device isolation. The arsenic implant reduces the contact resistance of subsequently formed metal to these regions, while the phosphorus implant defines the active concentration of the collector portion 210 and emitter 104. Emitter 104 is self-aligned to insulating layer 106-1, which in turn is aligned to conductive layer 116 and to stack 229. Therefore, emitter 104 is self-aligned to base 110. By way of comparison, in conventional vertical bipolar transistors, the depth of the emitter and base regions is defined by implant energy and vertical diffusion. In accordance with an aspect of the present invention, however, the base profile can be precisely tailored in accordance with the thickness of conductive layer 116 and insulating layer 106-1.

After implantation 234, a 30 sec RTA is carried out at 950° C. to activate all dopants, while minimizing lateral diffusion so that a more abrupt junction can be achieved between base 110 and emitter 104. Preferably, such a box like or abrupt junction minimizes base width and improves transistor speed.

In final stages of the process of fabricating, silicide layers 238 are preferably deposited in order to reduce contact resistance to collector portion 120, emitter 104, and conductive layer 124 connected to base 110 (FIG. 2(j)). Prior to depositing silicide layers 238, the conductive layer 124 is typically exposed by removing insulating layer 114. However, in doing so, a comparable portion of Box oxide layer 102 having a thickness substantially equal to that of insulating layer 114 may also be removed thereby exposing the underlying silicon substrate. Accordingly, the thickness of insulating layer 114 is preferably selected so that the BOX oxide is not completely etched away in regions not covered by semiconductor layer 105 of the completed device (corresponding to layers 212 and 214 discussed above.

Salicidation is achieved by sputtering titanium and a subsequent anneal to form self-aligned Titanium Silicide (TiSix) across all exposed silicon and polysilicon areas to form silicide layers 238. Any un-reacted titanium is removed. Note that due to the presence of insulating or silicon nitride layer 250, for example, no TiSiₓ is formed between adjacent devices, and thus all devices are isolated.

A thick layer of borophosphosilicate glass (BPSG) 240 or other suitable insulator is then deposited. Contact holes 252 are opened with a contact (CNT) mask. The lateral lengths of conductive layer 124, emitter 104 and collector portion 120 are limited by the lithography resolution to accommodate at least one of contact holes 252. A thick layer of aluminum 236 or other appropriate conductor is then sputtered and patterned in a conventional manner. The completed structure is shown in FIG. 2(j), including the other side of the device.

The above-described process may be used to fabricate transistor 100 suitable for HV applications. In such applications, the base width is preferably larger than in high speed (HS) applications. A modified process (hereinafter the “HS process”) for forming transistor 100 for such applications is similar to that described above. However, the initial implantation 218 in FIG. 2(c) is omitted. Instead, after conductive layer 116 is formed in step 2(f), double implant 310 of BF₂ (120 keV, 1.5×10¹³ cm⁻²) and Boron (50 keV, 10¹³ cm⁻²) with 0° substrate tilt is carried out (FIG. 3(a)). SIMS data associated with implant 310 is represented by curve 410 shown in FIG. 4.

Remaining steps of the HS process are the same as in the process shown in FIGS. 2(a) to 2(j), and the completed HS device is shown in is shown in FIG. 3(b). It is noted that bases 312 have edge 320 and 322, respectively, which are self-aligned with surfaces 127 of conductive layers 116. Accordingly, base 312 is narrower than base 101, which has edge 132 self-aligned with sidewall 126 of conductive layer 124 instead (see FIGS. 1 and 2(j)).

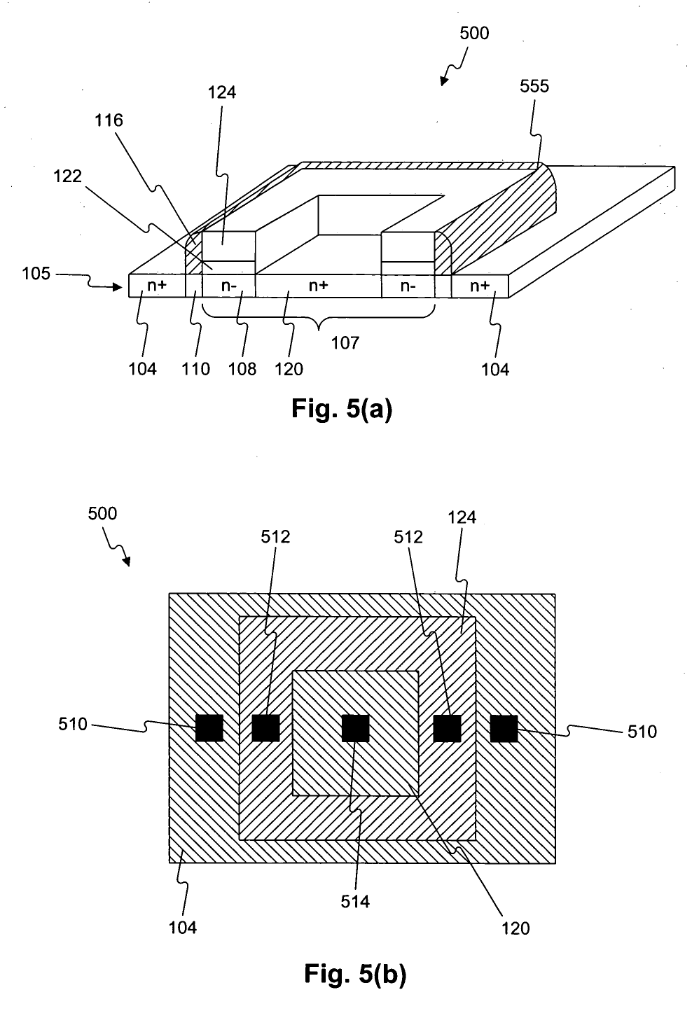

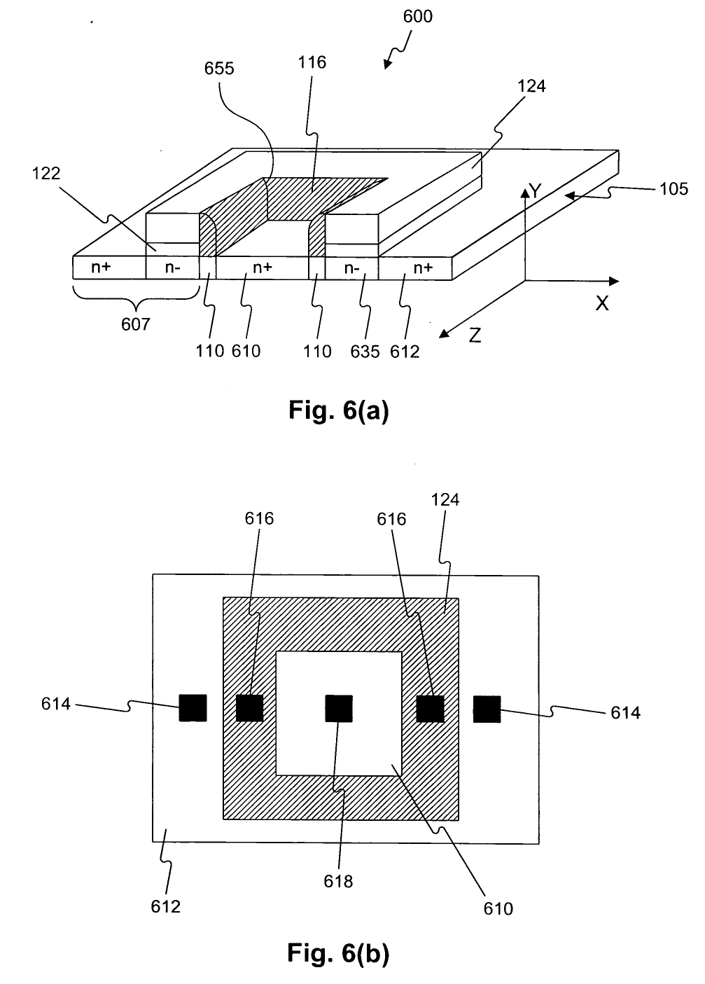

FIGS. 5(a), 5(b) and 6(a), 6(b) illustrate alternative transistor configurations consistent with a further aspect of the present invention. FIGS. 5(a) and 5(b) are perspective and plan views, respectively, of common-emitter configuration 500 in which emitter 104 surrounds or encircles base 110. Base 110, in turn, surrounds or encircles collector 107. Conductive layers 124 and 116 overly LDC portion 118 and base 110, respectively. As further shown in FIGS. 5(a) and 5(b), emitter 104 is accessible from every planar direction. Thus two transistors can be connected together by sharing the outer portions of emitter 104. Contacts 510, 512 and 514 provide electrical connection to emitter 104, conductive layer 124 (and thus base 110), and collector portion 120, respectively.

FIGS. 6(a) and 6(b) are perspective and plan views of a common collector configuration 600 in which collector 607, including lightly and heavily doped portions 635 and 612, respectively, en-circles or surrounds base 110, which, in turn, encircles or surrounds emitter 610. Contacts 614, 616 and 618 provided electrical connection to collector portion 612, base 110 and emitter 610, respectively. Advantageously, the vertical cross-sectional area of semiconductor layer 105 beneath the inner and outer edges of conductive layer 124 is comparable to that of the active area in conventional bipolar junction transistors.

In FIGS. 5(a), 5(b), 6(a) and 6(b), since conductive layers 124 and 116 in both vertical planes (x-y, y-z plane) are physically identical, the horizontal cross section in any direction is almost identical. Only at corners 555 and 655, for example, the thickness of conductive layer 116 may slightly increase, thereby enlarging the width of the self-aligned base of 110. This results in reducing current in these areas and forming dead zones. However, such dead-zones are mostly eliminated in transistor 100, reducing overall three dimensional parasitic junctions, which are otherwise present in conventional vertical and lateral bipolar junction transistor designs. Also, the emitter area to base area ratio (A_{E}/A_{B}) in both configurations 500 and 600 is approximately equal to unity. In conventional vertical designs, however, this ratio is between 0.5-0.8.

Moreover, in configurations 500 and 600, current flows horizontally, and the length and width of conductive layer 124 controls the amount of conduction current as in CMOS transistors. In CMOS, however, the current multiplication factor is defined as (WIL), but consistent with an aspect of the present invention, the current multiplication factor is the circumference of area of emitter 104 (FIG. 5(a) or emitter 610 (FIG. 6(a), which is (2×(L_{E}+W_{E})). Since all four planes are used for current conduction, more current can flow through configurations 500 and 600 per chip area. It is believed that no other bipolar transistor conducts current flow in more than one-plane or direction.

Consistent with a further aspect of the present invention, higher current drive, smaller chip area, more design flexibility, and compactness can be achieved. By way of comparison, a typical RF bipolar junction transistor (BJT) has an emitter area of 2 μm² (4×0.5) and an active area of about 80 μm². For an equivalent emitter area consistent with the present invention, an active area of only 40 μm² is required, provided that semiconductor layer 105 has a thickness of about 0.19 μm. Naturally, as the thickness of semiconductor layer 105 decreases, this advantage will disappear, but such semiconductor layers, i.e., thin-film SOI layers, are generally used for low power applications, and the amount of current drive can be designed accordingly. For circuit designers, there is more flexibility to size transistors similar to CMOS. Also, with the availability of both common emitter 500 and common collector 600 configurations, devices can be connected through shared collector or emitter areas, thereby realizing more compact designs with less interconnect parasitics.

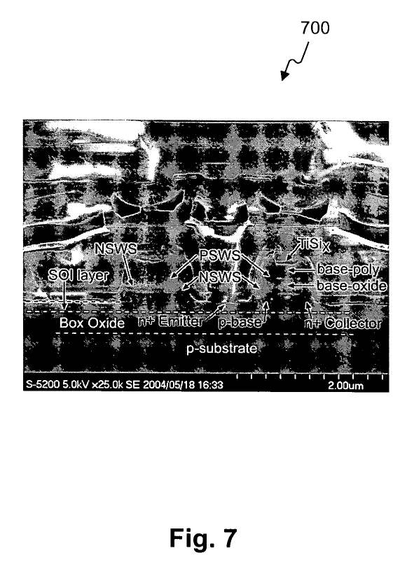

An SEM micrograph 700 of an example of common collector configuration 600 consistent with the present invention is shown in FIG. 7. The polysilicon sidewall spacer (“PSWS”) corresponding to conductive layer 116 is formed vertically against a poly-base stack including “base-poly” and “base-oxide” (corresponding to insulating layer 122 and conductive layer 124, respectively), and is sandwiched by the NSWS (corresponding to insulating layers 106-1 and 106-2) on both sides of the stack. The PSWS connects the base-poly and the p-base regions. The emitter, collector and base diffusion regions are as indicated in FIG. 7. Due to the over-etching process required to form both the PSWS and NSWS (see FIGS. 2(f) and 2(i)), slight over etching of the SOI (corresponding to semiconductor layer 105, also represented as layer 214) is observed. Also, the salicidation process that forms TiSiₓ (as shown in the black area in FIG. 7, see also FIG. 2(j)) consumes some additional silicon. Therefore, the SOI layer thickness at the collector/emitter area is much thinner.

Advantageously, the processes described above with respect to FIGS. 2(a) to 2(j), 3(a) and 3(b), for example, eliminates trench isolation, epitaxy and the n+buried layer, which are required features in conventional vertical BJTs. Moreover, transistor 100 can be made in only 5 mask or photolithography steps, including one to separate HS and HV devices. This is the lowest of all vertical or lateral BJTs. Also, one additional mask step can be eliminated if only one type of device (HS or HV) is required, and both common emitter 500 and common collector 600 configurations are implemented. In addition, as noted above, consistent with an aspect of the present invention, transistors 100 are self isolated, and therefore no trench isolation process is needed.

PNP bipolar and CMOS transistors can also be integrated with transistors consistent with the present invention to create a full complimentary BiCMOS process. In which case, an additional mask is needed to shield the NPN devices during PNP device processing. But for the presence of PSWS layer (conductive layer 116) and a much thicker gate-oxide, the transistor shown in FIG. 7 has similar structures as those found in CMOS devices. Due to such similarities, the transistor consistent with the present invention can be fabricated with a so-called “Base-With-Gate” topology. Moreover, a multi-gate-oxide process can be used to obtain different thicknesses for both the gate/base-oxides. The same poly can be subsequently deposited to form the gate/base-poly for the CMOS/Bipolar devices. However, an extra blanket mask may be needed to insure that the PSWS (conductive layer 116) only forms on the lateral bipolar junction transistor, and not the CMOS devices. One of ordinary skill would appreciate that remaining processing steps can be further economized, and the overall number of masking and/or processing steps reduced.

Similar to SiGe HBT BiCMOS technology, so-called “Base-After-Gate” topology can also be used to integrate transistors consistent with the present invention with CMOS devices. The CMOS gate structures can be first constructed, followed by a blanket mask that covers the CMOS regions. Then transistors consistent with the present invention can be constructed on the un-masked regions, followed by removal of the blanket mask and thermal annealing for both Bipolar and CMOS devices. By way of comparison, the advantage of Base-With-Gate topology results in reduction in cost and processing time, but the bipolar/CMOS transistor characteristics are compromised by this simplified process. The Base-After-Gate topology has the advantage of greater flexibility for device optimization at the cost of more masking and processing steps. Nevertheless, both topologies can achieve full BiCMOS integration.

The electrical properties of transistors consistent with the present invention will next be described. In particular, electrical characteristics were measured for both HS and HV versions, and for both common emitter and common collector configurations. Since common collector and common emitter devices exhibit similar properties, and only the active areas are different due to different layouts as noted above with respect to FIGS. 5(a), 5(b), 6(a) and 6(b), common emitter type devices will be discussed in detail out of convenience. The performance of both HV and HS devices are summarized in Table 1, which lists an f_{τ} of the HS device of 17 GHz, which is believed to be the second highest f_{τ} for an LBJT reported so far. Such high f_{τ} is believed to be attributable to reduced parasitics in the transistor consistent with the present invention. Also, the HV device achieves f_{τ} and collector-emitter breakdown voltage (BV_{CEO}) of 12 GHz and 27.5V, respectively. This produces a Johnson's product of 330 GHz·V. The value of BV_{CEO} is believed to be the highest for devices that operate above 10 GHz, and the Johnson's product matches the theoretical limit of 320-340 GHz·V. It is noted that the measured BV_{CEO} for the HS device is smaller than HV device, apparently due to premature punchthrough breakdown because the thin base was used to push for higher speed.

TABLE I
SUMMARY OF DEVICE PERFORMANCE FOR HS/HV
TRANSISTORS

| Parameters | HS | | HV | | Note |
|---|---|---|---|---|---|
| A_{E} | 0.19 × 12 | μm² | 0.19 × 15 | μm² | — |
| h_{EE} | 77 | | 36 | | V_{CE} = 2 V, |
| | | | | | V_{BE} = 0.8 V |
| Peak | 17 | GHz | 12 | GHz | V_{CE} = 1 V |
| fᵣ | | | | | |
| Peak | 28 | GHz | 30 | GHz | V_{CE} = 1 V |
| fₘₐₓ | | | | | |
| V_{A} | 4.0 | V | 12.6 | V | V_{CE} = 3 V, |
| | | | | | I_{B} = 1 μA |
| BV_{CEO} | 4.3 | V | 27.5 | V | I_{C} = 1 μA |
| BV_{CBO} | 21.9 | V | 33.6 | V | I_{C} = 1 μA |
| BV_{EBO} | 8.6 | V | 8 | V | I_{E} = 1 μA |

In Table I, BV_{CBO} and BV_{EBO} correspond to collector-base and emitter-base breakdown voltages, respectively.

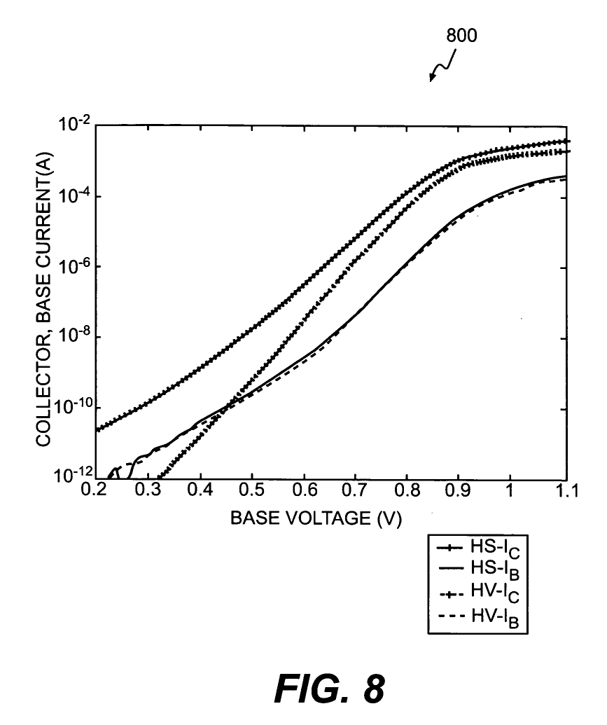

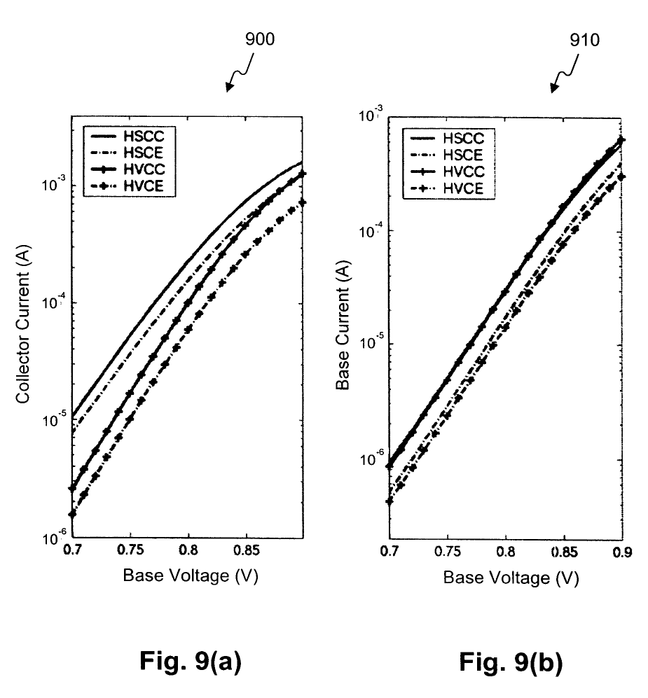

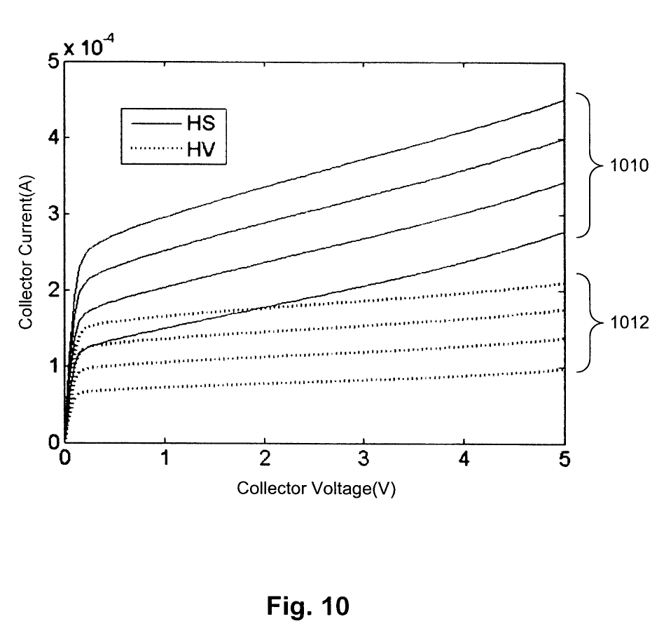

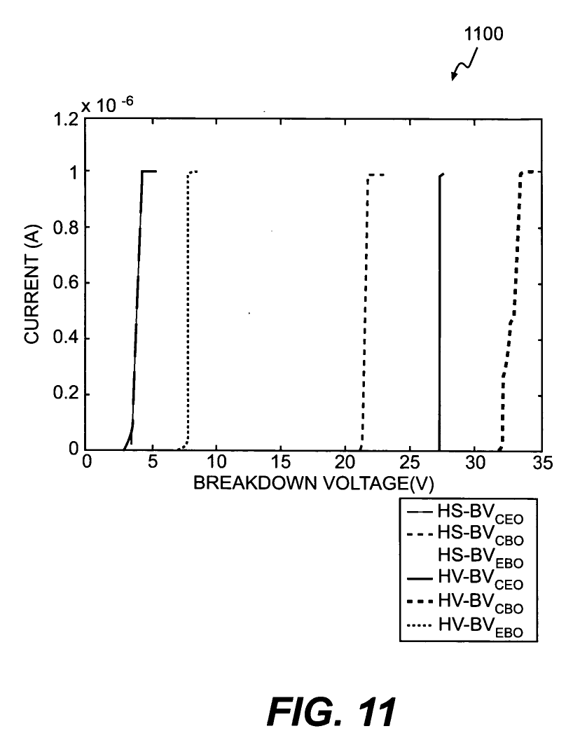

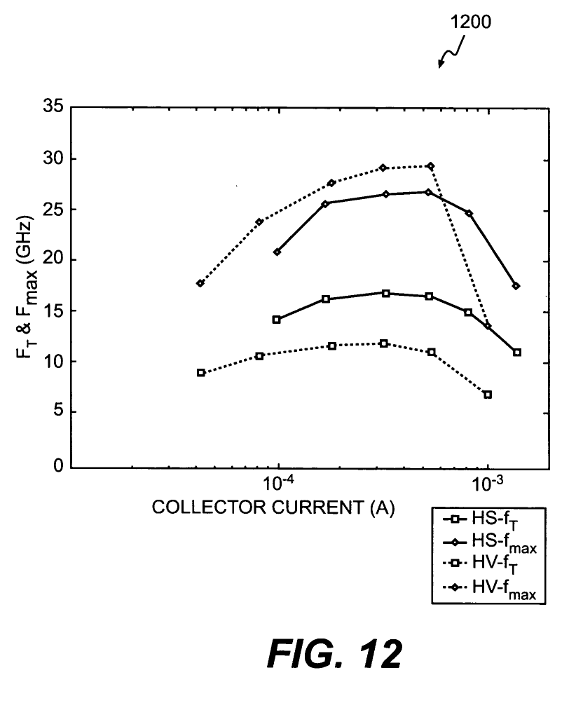

Gummel plots 800, which in this example, are plots of collector and base current vs. base voltage, for both the HS and HV transistors in the common emitter configuration are depicted in FIG. 8. The active areas for the measured HS and HV devices are 2.28 μm² and 2.85 μm², respectively. A comparison of the voltage-current characteristics of common collector and common emitter configurations is shown in FIG. 9. The active areas of the corresponding common collector type devices in this example are 3.8 μm² and 5.7 μm², respectively. As evidenced by the Gummel plots 900 and 910 of FIG. 9, the common collector and common emitter configurations scale well with respect to the size of the active area. Examples of output characteristics (I_{C}-V_{CE}) 1010 and 1012 of transistors consistent with the present invention are shown in FIG. 10. Due to the thin base of the HS device, the avalanche breakdown voltage V_{A} is only 4V compare to 12.6V for the HV devices. The three breakdown characteristics 100 of the transistor, BV_{CEO}, BV_{CBO} and BV_{EBO} are shown in FIG. 11. Although BV_{CEO} is lower for HS devices, it's sufficient for systems that operate with a power supply of 2-3V. Ironically, the BV_{CEO} of the HV device exceeds that for most RF applications. With adequate base optimization, such as reducing PSWS (conductive layer 16) thickness for thinner base width or reducing base implant dose for lower base doping, BV_{CEO} can be reduced but with increased f_{τ} and fₘₐₓ, while maintaining a similar Johnson's product. The S-parameters, which represent reflected and transmitted microwave energy of the transistors were evaluated from 200 MHz to 15 GHz. f_{τ} is calculated based on one the extracted S-parameters, namely the H₂₁ parameter, and fₘₐₓ is calculated from the Unilateral power gain. The f_{τ}-I_{C} and fₘₐₓ-I_{C} characteristics 1200 for both transistors are plotted in FIG. 12. Peak f_{τ} and fₘₐₓ of 17 and 28 GHz are reached at I_{C} of 0.4 mA for the HS device. At similar current levels, peak f_{τ} and fₘₐₓ of 12 and 30 GHz are achieved for the HV device.

Consistent with the present invention, a lateral bipolar junction transistor is provided that is compatible CMOS and can be fabricated on SOI. This technology requires simple PSWS (conductive layer 16) structure and can be fabricated with only five lithography masks to realize high performance devices. A novel layout methodology is used to form area efficient devices in both common emitter and common collector configurations, thus increasing design compactness and flexibility. It is believed that the transistors disclosed herein are the first to have emitter current injection in multiple planes.

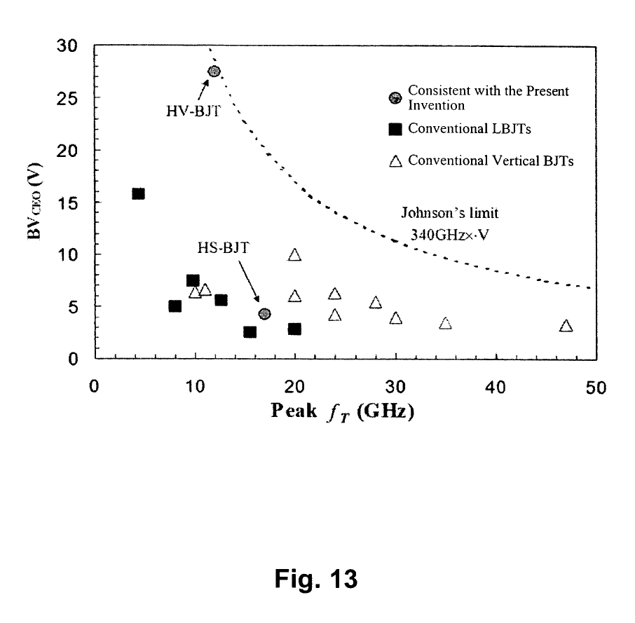

The electrical characteristics are measured and summarized in Table II, with comparison data from previously published lateral bipolar junction transistors (LBJTs). (T. Suligoj et al. “Fabrication of Horizontal Current Bipolar Transistor (HCBT)”, IEEE Trans. Electron Devices, vol. 50, pp. 1645-1651, July 2003; H. Nii et al., “A novel lateral bipolar transistor with 67 GHz f max on thin-film SOI for RF analog applications,” IEEE Trans. Electron Devices, vol. 47, pp. 1536-1541, July, 2000; T. Shino et al., “A 31 GHz fmax lateral BJT on SOI using self-aligned external base formation technology,” in IEDM Tech. Dig., 1998, pp. 953-956; and R. Dekker et al., “An ultra low power lateral bipolar polysilicon emitter technology on SOI,” IEDM Tech. Dig., 1998, pp. 953-956.) Notably, the external base width (WBₑₓₜ) is not limited by photolithography, and a minimum width of 0.1 μm is achieved. The novel PSWS design greatly reduces parasitic capacitance that translates into higher frequency performance. It is believed that the measured f_{τ} of 17 GHz is the second highest reported and fₘₐₓ of around 30 GHz is high taking into account that conventional materials can be used to fabricate the transistor consistent with the present invention. The Johnson's product for the HV device is the highest reported for silicon BJT (depicted in FIG. 13), exceeding not only conventional lateral BJTs but conventional vertical BJTs that incorporate smaller lithography and epitaxial base processes. One of ordinary skill would appreciate that by improving the base resistance and optimizing the base doping, even higher f_{τ}/fₘₐₓ can be obtained. This low cost bipolar transistor consistent with the present invention is suitable for SOI-CMOS integration, as well as BiCMOS processes for future RF SoC applications.

TABLE II
SUMMARY OF PROCESS AND PERFORMANCE OF PSWS LBJT
COMPARED WITH PREVIOUSLY PUBLISHED LBJTS.

| | | Suligoj et al. | | Shino et al. | Dekker et |
|---|---|---|---|---|---|
| | This work | [16] | Nii et al. [15] | [14] | al. [13] |
| Year | 2004 | 2003 | 2000 | 1998 | 1993 |
| Ext. Base | PSWS | Poly | Co Salicide | Poly | Poly |
| WBₑₓₜ (μm) | 0.1 | 3 | 0.5 | 0.5 | 0.5 |
| fᵣ (GHz) | 17/12 | 4.4 | 12.6 | 9.8 | 15.5 |
| fₘₐₓ (GHz) | 28/30 | 12 | 67 | 31 | 13 |
| BV_{CEO} (V) | 4.3/27.5 | 15.8 | 5.6 | 7.4 | 2.5 |
| fᵣ × BV_{CEO} (GHz · V) | 73.1/330 | 69.5 | 70.5 | 72.5 | 32.5 |

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A semiconductor device, comprising:
a substrate;
a semiconductor layer provided on the substrate;
a collector region having a first conductivity type provided in the semiconductor layer;
an emitter region having the first conductivity type provided in the semiconductor layer laterally spaced from the collector region;
a base region having a second conductivity type provided between the emitter and collector regions, the base region having a first concentration of impurities of the second conductivity type;
a contact region provided in the base region, the contact region having a second concentration of the impurities of the second conductivity type greater than the first concentration;
a first conductive layer provided on a surface of the substrate, the first conductive layer having a sidewall; and
a second conductive layer, a first portion of the second conductive layer contacting the sidewall and a second portion of the second conductive layer contacting the contact region.

2. A semiconductor device in accordance with claim 1, wherein said first portion of the second conductive layer includes a first surface, the second conductive layer having a second surface, the semiconductor device further comprising an insulating layer provided on the second surface of the second conductive layer.

3. A semiconductor device in accordance with claim 2, wherein an edge of the emitter region is self aligned with the second surface of the second conductive layer.

4. A semiconductor device in accordance with claim 1, further comprising an insulating layer provided between the first conductive layer and the surface of the semiconductor layer.

5. A semiconductor device in accordance with claim 1, further comprising:
a first insulating layer provided between the first conductive layer and the surface of the semiconductor layer; and
a second insulating layer provided on the first conductive layer.

6. A semiconductor device in accordance with claim 1, wherein the first and second conductive layers include polysilicon.

7. A semiconductor device in accordance with claim 1, wherein the substrate is insulative.

8. A semiconductor device in accordance with claim 2, wherein the insulating layer includes silicon nitride.

9. A semiconductor device in accordance with claim 1, wherein an edge of the base region is self aligned with the sidewall of the first conductive layer.

10. A semiconductor device in accordance with claim 1, wherein said first portion of the second conductive layer includes a first surface, the second conductive layer having a second surface, an edge of the base region being self aligned with the second surface of the second conductive layer.

11. A semiconductor device in accordance with claim 1, wherein the collector region includes a first portion having a first impurity concentration and a second portion having a second impurity concentration less than the first impurity concentration, the second portion of the collector region being provided between the first portion of the collector region and the base region.

12. A semiconductor device in accordance with claim 11, wherein the first conductive layer is provided over the second portion of the collector region.

13. A semiconductor device, comprising:
a substrate;
a semiconductor layer provided on the substrate;
a collector region provided in the semiconductor layer, the collector region having a first conductivity type;
a base region provided in the semiconductor layer, the base region having a second conductivity type, the collector region surrounding the base region; and
an emitter region provided in the semiconductor layer, the base region surrounding the emitter region.

14. A semiconductor device in accordance with claim 13, wherein the base region has a first concentration of impurities of the second conductivity type, the semiconductor device further comprising:
a contact region provided in the base region, the contact region having a second concentration of the impurities of the second conductivity type, the second concentration being greater than the first concentration;
a first conductive layer provided on a surface of the substrate, the first conductive layer having a sidewall; and
a second conductive layer contacting the sidewall of the first conductive layer and the contact region.

15. A semiconductor device in accordance with claim 13, wherein the emitter region includes a first portion having a first impurity concentration and a second portion having a second impurity concentration less than the first impurity concentration, the second portion of the emitter region being provided between the first portion of the emitter region and the base region.

16. A semiconductor device, comprising:
a substrate;
a semiconductor layer provided on the substrate;
an emitter region provided in the semiconductor layer, the emitter region having a first conductivity type;
a base region provided in the semiconductor layer, the emitter region surrounding the base region; and
a collector region provided in the semiconductor layer, the base region surrounding the collector region.

17. A semiconductor device in accordance with claim 16, wherein the base region has a first concentration of impurities of the second conductivity type, the semiconductor device further comprising:
a contact region provided in the base region, the contact region having a second concentration of the impurities of the second conductivity type, the second concentration being greater than the first concentration;
a first conductive layer provided on a surface of the substrate, the first conductive layer having a sidewall; and
a second conductive layer contacting the sidewall of the first conductive layer and the contact region.

18. A semiconductor device in accordance with claim 16, wherein the emitter region includes a first portion having a first impurity concentration and a second portion having a second impurity concentration less than the first impurity concentration, the second portion of the emitter region being provided between the first portion of the emitter region and the base region.

19. A method of manufacturing a semiconductor device, comprising:
forming a semiconductor layer having a first conductivity type on a substrate, the semiconductor layer having a first concentration of impurities of the first conductivity type;
forming an insulating layer on the surface of the substrate;
forming a first conductive layer on the insulating layer;
patterning the insulating and first conductive layers such that a sidewall of the first conductive layer is aligned with a sidewall of the insulating layer;
forming a second conductive layer on the sidewalls of the insulating and first conductive layers;
forming a first doped region in the semiconductor layer in contact with the second conductive layer, the first doped region having a second conductivity type; and
forming a second doped region having the first conductivity type in the semiconductor layer, the second doped region having a second concentration of impurities of the first conductivity type and being spaced from a portion of the semiconductor layer having the first concentration of the impurities of the first conductivity type, the first doped region being provided between the second doped region and the portion of the semiconductor layer.

20. A method in accordance with claim 19, wherein the second conductive layer includes polysilicon having impurities of the second conductivity type, and the forming the first doped region includes diffusing the impurities of the second conductivity type from the second conductive layer into the semiconductor layer.

21. A method in accordance with claim 19, wherein forming the second conductive layer includes:
depositing a conductive material on the patterned insulating and first conductive layers; and
anisotropically etching the conductive material.

22. A method in accordance with claim 21, wherein the conductive material is polysilicon.

23. A method in accordance with claim 19, wherein the patterned insulating layer is a first insulating layer, the method further comprising:
depositing an insulating material on the first insulating layer and the patterned first conductive layer; and
anisotropically etching the insulating material to form a second insulating layer on a surface of the first conductive layer.

24. A method in accordance with claim 23, further comprising implanting the impurities of the first conductivity type of the second doped region, an edge of the implanted impurities of the first conductivity type of the second doped region being aligned with a surface of the second insulating layer.

25. A method in accordance with claim 19, further comprising implanting dopants to form a second conductivity type region in the semiconductor layer, an edge of the second conductivity type region being aligned with the sidewalls of the insulating and first conductive layers.

26. A method in accordance with claim 19, further comprising implanting dopants to form a second conductivity type region in the semiconductor layer, an edge of the second conductivity type region being aligned with a surface of the second conductive layer.

27. A method in accordance with claim 19, wherein substrate is insulating, and the forming the semiconductor layer includes depositing the semiconductor layer on the substrate.

28. A method in accordance with claim 19, further comprising forming a third doped region in the semiconductor layer, the third doped region having the first conductivity type, the first doped region being provided between the second doped region and the third doped region.

29. A method in accordance with claim 28, wherein the first, second and third doped regions form portions of a base, emitter and collector, respectively, of a bipolar transistor.

30. A semiconductor device in accordance with claim 1, further comprising a layer of silicide in contact with the first conductive layer.

31. A method in accordance with claim 19, further comprising forming a layer of suicide in contact with the first conductive layer.
